(19) United States
(12) Patent Application Publication
(10) Pub. No.: US 2026/0370118 A1
(43) Pub. Date: Nov. 19, 2026

(54) ASYMMETRIC PHASE INTERLEAVING

(71) Applicant: Micron Technology, Inc., Boise, ID (US)

(72) Inventors: Akashdip Das, Kolkata (IN); Alimi Rakesh Kumar, Jagityal (IN); Leela Madhav Lakkimsetti, Bangalore (IN)

(21) Appl. No.: 19/672,019

(22) Filed: May 8, 2026

Related U.S. Application Data
(60) Provisional application No. 63/804,859, filed on May 13, 2025.

(51) Int. Cl. H02M 1/00; H02M 1/088; H02M 1/14; H02M 3/156; H02M 3/158; H03K 17/284

(52) U.S. Cl. CPC H02M 1/0043; H02M 1/088; H02M 1/143; H02M 3/1566; H02M 3/1582; H03K 17/284; H03K 2217/0063; H03K 2217/0072

(57) ABSTRACT

Apparatuses and methods for operating a regulator with asymmetric phase interleaving are described. The asymmetric phase interleaving can be achieved by in traducing a delay (e.g., by a particular amount) in activating a high-side switch of one of phases of the regulator. The interleaving delay can offer a more flexible approach that allows compensation ramp heights to be dynamically optimized for various duty cycles.

### PRIORITY INFORMATION

This application claims the benefits of U.S. Provisional Application No. 63/804,859, filed on May 13, 2025, the contents of which are incorporated herein by reference.

### TECHNICAL FIELD

The present disclosure relates generally to electronic apparatuses and methods, and more particularly, to apparatuses and methods related to asymmetric phase interleaving associated with operating regulators.

### BACKGROUND

Voltage regulators play essential roles in supplying power to subsystems with distinct voltage and current needs. Linear regulators offer simplicity and low noise, while switching regulators, such as buck, boost, and buck-boost converters, achieve high efficiency for variable loads. For example, power management integrated circuits (PMICs) often integrate multiple voltage regulators and other functions, reducing board space and complexity while ensuring precise coordination across power rails in devices like smartphones, laptops, and embedded systems.

### BRIEF DESCRIPTION OF THE DRAWINGS

FIG. 1 illustrates an example electronic system that includes a voltage regulation component in accordance with some embodiments of the present disclosure.

FIG. 2 illustrates a switching voltage regulator having a phase manager that operates in conjunction with a timer in accordance with some embodiments of the present disclosure.

FIG. 3 is a flow diagram corresponding to a method for operating a voltage regulator with asymmetric phase interleaving in accordance with some embodiments of the present disclosure.

FIG. 4 illustrates graphs showing currents of inductors of a voltage regulator exhibiting asymmetric interleaving in accordance with some embodiments of the present disclosure.

FIG. 5 illustrates graphs showing states of various signals during operation of a regulator during a load application transient in accordance with some embodiments of the present disclosure.

FIG. 6 is a flow diagram corresponding to a method for operating a voltage regulator with asymmetric phase interleaving in accordance with some embodiments of the present disclosure.

### DETAILED DESCRIPTION

Systems, apparatuses, and methods related to asymmetric phase interleaving associated with operating regulators are described. Switching voltage regulators, such as Constant-On-Time (COT) DC-DC converters, are employed in various electronic systems to efficiently regulate output voltage across a range of load conditions.

Some dual-phase DC-DC converters (e.g., step down votlage regulators) may rely on symmetric interleaving, where inductor currents naturally settle at 180° out of phase because of the feedback. While this may reduce ripple under specific operating conditions, it can lead to significant limitations. Ripple cancellation can cause the effective compensation ramp height to diminish, increasing susceptibility to noise and making the system frequency unstable. This can introduce practical challenges in maintaining noise immunity and stability, particularly in Continuous Conduction Mode (CCM), where reduced ramp height exacerbates comparator sensitivity and leads to jitter on the switching frequency.

In some approaches, external ramp compensation techniques have been employed to address low ramp height by introducing artificial ramps. However, these approaches can increase circuit complexity and often degrade transient performance, resulting in overshoots and undershoots that increases the circuit complexity of frequency stabilization of the voltage control loop. Additionally, these methods may not fully resolve the vulnerability to noise, especially across a wide range of duty cycles, limiting their effectiveness in dynamic environments.

These approaches are further constrained by a lack of flexibility in interleaving delays, as the two inductor currents of the dual-phase DC-DC switching regulator typically settles to 180° out of phase with respect to one another, which can prevent optimization of performance under varying load conditions and transient events. Moreover, these approaches can be limited by fixed input and output voltage constraints, narrowing their duty cycle range and reducing adaptability to diverse system requirements. Further, the compensation ramp height and transient performance are interlinked such that when the compensation ramp height is increased, the transient performance deteriorates while there is an improvement in noise immunity and therefore the jitter performance. If the compensation ramp height is decreased, transient performance improves while the noise immunity and therefore the jitter performance deteriorates. The cumulative result of these limitations can be an architecture that struggles to deliver stable and noise-immune performance, particularly in scenarios requiring precise load regulation and robust transient response from a dual phase DC-DC step down voltage regulator.

Aspects of the present disclosure address the above and other challenges by introducing a programmable interleaving delay mechanism between the two phases, to improve system stability and transient performance in dual-phase DC-DC converters during a CCM operation. Embodiments of the present disclosure can leverage a dynamic control loop modification that generates a signal for activating a high-side switch of the second phase circuit subsequent to the additional programmable interleaving delay (in addition to the high-side switch ON time of the first phase circuit). The programmable interleaving delay can offer a more flexible approach that allows compensation ramp heights to be dynamically optimized for various duty cycles.

For example, at duty cycles near 0 or 0.5, where some approaches may suffer from ripple cancellation and low compensation ramp heights, embodiments of the present disclosure can improve ramp height by adjusting the programmable interleaving delay without an addition of an external ramp. This can reduce noise sensitivity and enhances jitter performance. The programmable delay can be optimized depending on input and output conditions, ensuring reliable performance across various operating points. While maintaining a stable summed current waveform and increasing ramp height, embodiments of the present disclosure can provide better noise immunity and transient response without adding complexity.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected. It is to be understood that data can be transferred, read, transmitted, received, or exchanged by electronic signals (e.g., current, voltage, etc.).

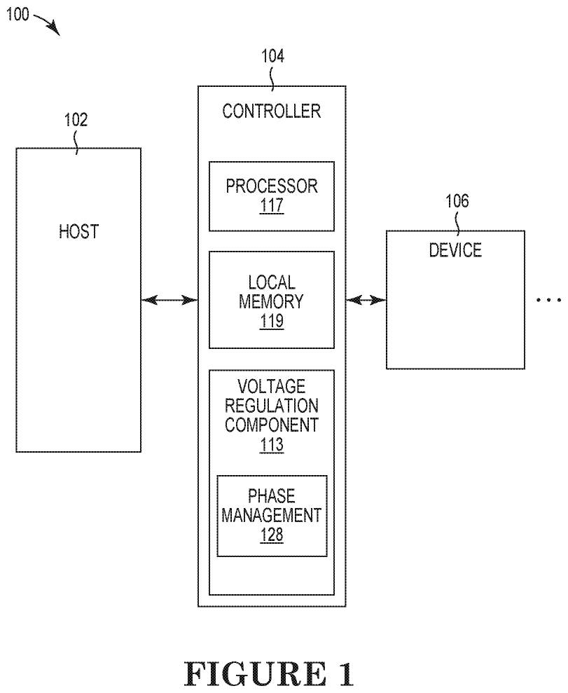

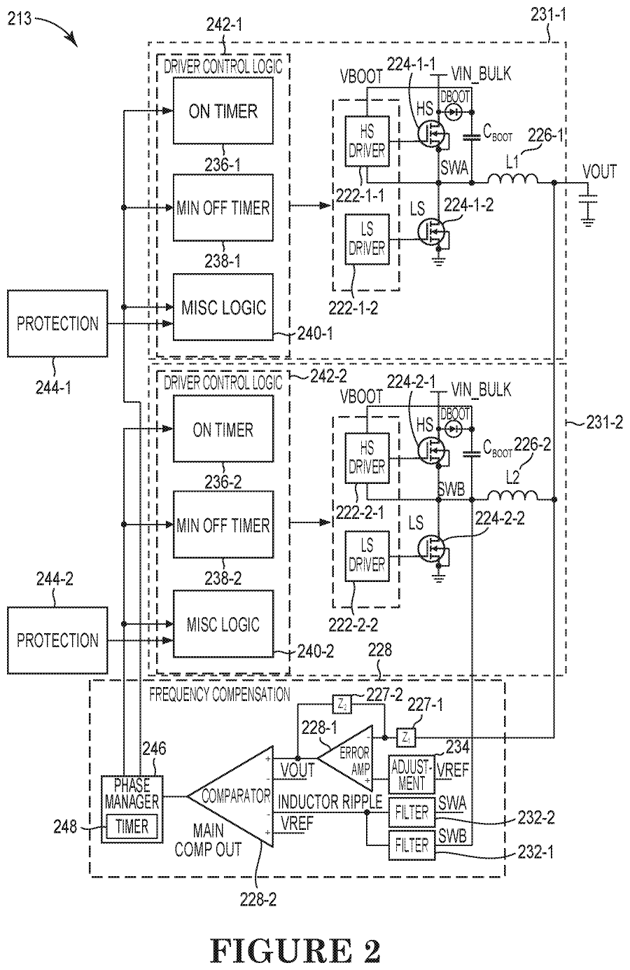

The figures herein follow a numbering convention in which the first digit or digits correspond to the drawing figure number and the remaining digits identify an element or component in the drawing. Similar elements or components between different figures may be identified by the use of similar digits. For example, 113 may reference element “13” in FIG. 1, and a similar element may be referenced as 213 in FIG. 2. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 illustrates an example electronic system 100 that includes a host 102, a controller 104, and a device 106 in accordance with various embodiments of the present disclosure. While the electronic system 100 can be considered as an apparatus, embodiments are not so limited. For example, the host 102, the controller 104, and the device 106 can each separately be considered as an apparatus.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 104 via a physical and/or logical host interface that operates based on various communication protocols and to provide control, address, data, and other signals to the controller 104 (e.g., to further cause the controller 104 to control the device 106). Examples of the interface between the host 102 and the controller 104 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 104 is communicatively coupled to one or more electronic devices 106 such that signaling can be exchanged therebetween. Non-limiting examples of the devices 106 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 104 can include a processing device (e.g., processor 117) that can execute instructions stored in a local memory 119 to perform various operations described herein. The controller 104 can include various special purpose circuitry in the form of an ASIC, FPGA, state machine, and/or other logic circuitry that can perform operations described herein. As an example, the controller 104 can be a memory controller.

In various embodiments, one or more constituent components (e.g., host 102, controller 104, device 106, etc.) of system 100 can be part of a SoC. In one example, a device 106 itself can correspond to an SoC, while the host 102 and the controller 104 are considered “external” to the SoC. In another example, the host 102 or the controller 104, or both, can be considered as a part of an SoC along with the device 106 being internal or external to the SoC.

In some embodiments, a device 106 can be a storage device, a memory module, or a hybrid of a storage device and memory module. Examples of a storage device include an SSD, a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

For example, the electronic device 106 can be a volatile or non-volatile memory device. In some embodiments, the electronic device 106 can be a DRAM array, SRAM array, STT RAM array, PCRAM array, TRAM array, RRAM array, NAND flash array, and/or NOR flash array, for instance. The arrays can comprise memory cells arranged in rows coupled by access lines (which may be referred to herein as word lines or select lines) and columns coupled by sense lines (which may be referred to herein as digit lines or data lines).

As shown in FIG. 1, the controller 104 can include a voltage regulation component 113 (e.g., a voltage regulator and/or converter). The voltage regulation component 113 can include one or more voltage regulators (e.g., the voltage regulator 213 shown in FIG. 2). The regulators can include a low-dropout (LDO) regulator, a buck-boost converter, a buck regulator, a boost regulator, or combination thereof, although embodiments are not so limited. More particularly, the voltage regulator 113 can be a dual-phase regulator that has a constant on time (COT) for duty cycles of those high-side switches (e.g., the high-side switches 224-1-1, 224-2-1 shown in FIG. 2).

As shown in FIG. 1, the voltage regulator 113 can operate in conjunction with a phase management component 128, which can indicate when to phase interleave among multiple phases of the voltage regulator 113. In a number of embodiments, the phase interleaving provided by the phase management component 128 can be asymmetrical in steady state CCM (Continuous Conduction Mode) in that the activation of one switch (e.g., the high-side switch 224-2-1 or the high-side switch 224-1-1) occurs after a programmable delay following the completion of the on time (tON) of the other switch (e.g., the high-side switch 224-2-1 or the high-side switch 224-1-1). Further details of operating the voltage regulator 113 in conjunction with the phase management component 128 are described in connection with FIGS. 2-4.

FIG. 2 illustrates a switching voltage regulator 213 having a phase manager 246 (alternatively referred to as a “phase splitter”) that operates in conjunction with a timer 248 in accordance with some embodiments of the present disclosure. Although embodiments are not so limited, the switching voltage regulator 213 may include step-up, step-down, or buck-boost DC-DC converters and, in some examples, multiple phase DC-DC converter.

The voltage regulator 213 can be a dual-phase regulator. For example, the voltage regulator 213 can include two independent switching circuits (alternatively referred to as “phase circuits”) where the inductor currents from each of the phases may be interleaved by a particular amount.

The first phase circuit 231-1 includes a high-side driver 222-1-1 (“HS DRIVER” shown in FIG. 2) and a low-side driver 222-1-2 (“LS DRIVER” shown in FIG. 2) that are respectively coupled to, and configured to control, switching elements or switches (alternatively referred to as “transistors”) 224-1-1, 224-1-2. Similarly, the second phase circuit 231-2 includes a high-side driver 222-2-1 (“HS DRIVER” shown in FIG. 2) and a low-side driver 222-2-2 (“LS DRIVER” shown in FIG. 2) that are respectively coupled to, and configured to control, switching elements or switches (alternatively referred to as “transistors”) 224-2-1, 224-2-2

Each high-side driver 222-1-1, 222-2-1 is configured to control the respective transistor 224-1-1, 224-2-1 that is placed between the (e.g., positive) power supply (“VIN_BULK” shown in FIG. 2 and alternatively referred to as “power source”) and the input of the respective inductor 226-1, 226-2, while each low-side driver 222-1-2, 222-2-2 is configured to control the respective transistor 224-1-2, 224-2-2 that is placed between the (e.g., positive) input of the inductor 226-1, 226-2 and ground.

For example, each driver 222-1-1, 222-2-1 can generate and apply a control signal to switch on the respective high-side transistor 224-1-1, 224-2-1, allowing current to flow from the positive power supply (“VIN_BULK” shown in FIG. 2) through the respective inductor 226-1, 226-2 to ground. For example, each driver 222-1-2, 226-2-2 can generate and apply a control signal to switch the low-side transistor 224-1-2, 224-2-2 on, allowing current to flow from the ground through the inductor via the transistor. Although embodiments are not so limited, the transistors 224-1-1, 224-1-2, 224-2-1, 224-2-2 can be metal-oxide-semiconductor field-effect (MOFSET) transistors.

Each driver logic 242-1, 242-2 can control the drivers 222-1-1, 222-1-2, 222-2-1, 222-2-2 in conjunction with various circuitry configured to provide timing, determining when the low and/or high switches are to be activated or deactivated, thereby alternating between the on-cycle and off-cycle. As used herein, the term “on-cycle” refers to the period during which switch 224-1-1, 224-2-1 is active (switched on), while the term “off-cycle” refers to the period during which switch 224-1-2, 224-2-2 is active (switched on). The on-cycle and off-cycle alternate, defining a duty cycle (the percentage of the “on-cycle” within a particular period of time).

For example, each driver logic 242-1, 242-2 can control the duration for which the respective high-side switch 224-1-1, 224-2-1 remains on based on timing indication provided from the respective timer 236-1, 236-2 (“ON TIMER” shown in FIG. 2), determining how much energy is delivered to the respective inductor 226-1, 226-2 (configured to provide “VOUT” shown in FIG. 2 and alternatively referred to as an output inductor) and output load (receiving power from the regulator 213) during each switching cycle. For example, each driver logic 242-1, 242-2 can operate to ensure that the low-side switch 224-2 remains on (after the high-side switch turns off) for a minimum specified time based on timing indication provided from the respective timer 238-1, 238-2 (“MIN OFF TIMER” shown in FIG. 2), preventing excessive switching and ensuring stability in the operation of the regulator. For example, each driver logic 242-1, 242-2 can manage additional control functions, such as fault protection (overcurrent, thermal shutdown, overvoltage protection), mode transitions, and synchronization with other parts of the system, ensuring safe, efficient, and reliable operation of the regulator, based on timing indication provided from the respective miscellaneous logic 240-1, 240-2 (“MISC LOGIC” shown in FIG. 2).

The regulator 213 further includes protection circuits 244-1, 244-2 (individually and/or collectively referred to as “protection circuit 244”) coupled to the miscellaneous logic 240-1, 240-2, respectively. The protection circuit 244 can be configured to monitor the system for issues such as overvoltage, undervoltage, overcurrent, overheating, etc., such as reverse voltage indicator (RVI) circuit, input over-voltage protection (OVP) circuit, etc. When a fault is detected, the protection circuit 244 can signal the respective miscellaneous logic 240-1, 240-2 to take corrective actions, such as adjusting the power output, disabling the system, or reducing power to protect the components. These circuits ensure the system operates safely and reliably under both normal and fault conditions.

As shown in FIG. 2, the regulator 213 also includes inductors 226-1, 226-2 (respectively in the two phase circuits 231-1, 231-2), which are located in the common node of the switches 224-1-1, 224-1-2 and the switches 224-2-1, 224-2-2, respectively. The inductor 226-1, 226-2 acts as an energy storage element. When the high-side switch 224-1-1, 224-2-1 is on, current flows from the supply through the inductor 226-1, 226-2 to the load (e.g., a circuit, component, device, etc. external to the regulator 213). During this stage, the inductor 226-1, 226-2 can store energy as well. When the low-side MOSFET 224-1-2, 224-2-2 is on, (and while the high-side MOSFET 224-1 is off) the inductor 226-1, 226-2 can continue supplying current to the load (e.g., a circuit, component, device external to the regulator 213 that the regulator 213 provides a regulated voltage) as it discharges its stored energy.

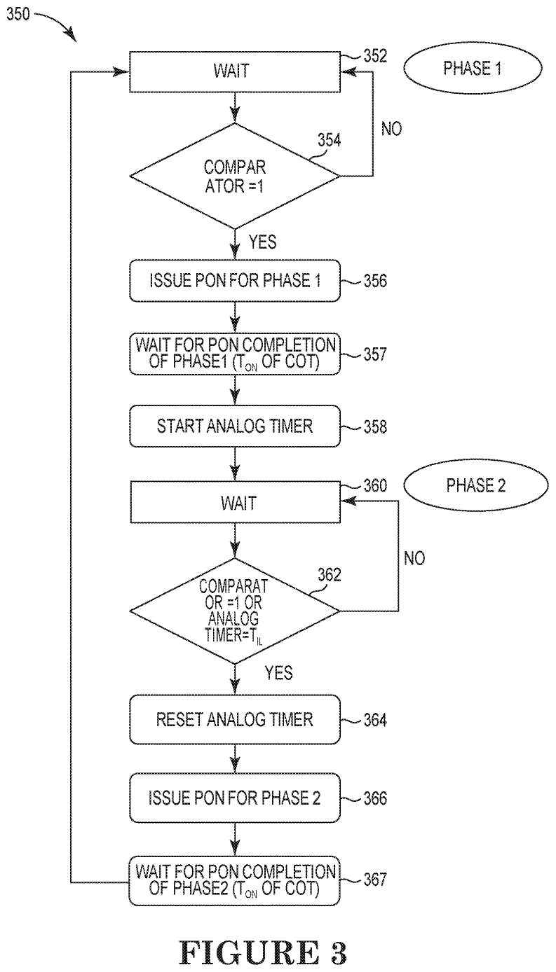

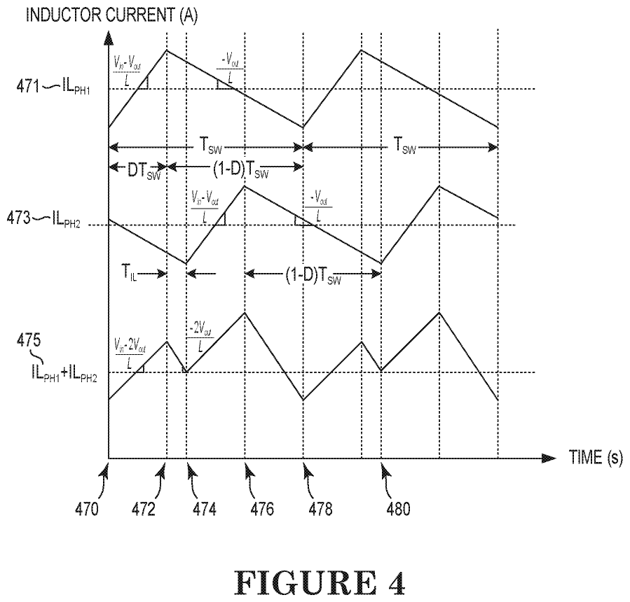

The driver logics 242-1, 242-2 can operate at different timings with respect to the activation of the high-side (e.g., switches 224-1-1, 224-2-1) and low-side switches (e.g., switches 224-2-1, 224-2-2) in each phase 231-1, 231-2. As used herein, the term “phase interleave” or the similar refers to a method of controlling operational timings of phase circuits 231-1, 231-2 based on the respective timings. In a number of embodiments, this “phase interleave” involves staggering the switching events of each phase asymmetrically (as further described in connection with FIGS. 3 and 4) if desired.

As shown in FIG. 2, the regulator 213 also includes a compensation system 228 coupled to both input and output nodes of the inductors 226-1, 226-2. Further, the compensation system 228 includes an error amplifier 228-1. The compensation system 228 further includes impedance elements 227-1 (“Z1” shown in FIG. 2), 227-2 (“Z2” shown in FIG. 2), which can be resistors, capacitors, inductors, RC (resistor-capacitor) networks, RL (resistor-inductor) networks, RLC (resistor-inductor-capacitor) networks, and/or diodes, although embodiments are not so limited. For example,

The impedance element 227-1 is located between the output of the error amplifier and one of inputs (e.g., the inverting input) of the error amplifier 228-1. More particularly, one side of the impedance element 227-1 is coupled to the output node of the inductor (“VOUT”) and the other side of the impedance element 227-1 is coupled to the inverting input of the error amplifier 228-1. The impedance element 227-2 can be connected between the inverting input and output of the error amplifier. The impedance element 227-1 functions as a voltage to current converter, taking the output voltage (“VOUT”) of the inductors 226-1, 226-2 and feeds it to the compensation system 228 of the error amplifier 228-1. Overall, this network formed of impedance elements 227-1, 227-2 can be a compensation network, which stabilizes the feedback loop by shaping the frequency response of the system, preventing oscillations and ensuring stability.

The error amplifier 228-1 further receives (at its non-verting input) an input voltage that corresponds to a reference voltage (“VREF” shown in FIG. 2) that can be adjusted by an adjustment circuit 234. The adjustment circuit 234 can be a soft-start circuit (e.g., which ramps up the voltage during startup), soft-off circuit (e.g., decreases the voltage during shutdown), dynamic voltage scaling (DVS) circuit (dynamically adjust the voltage based on load requirements), etc.

The error amplifier 228-1 outputs an output voltage, which can be an error signal. For example, the error amplifier 228-1 can generate an analog signal as an output signal based on the difference between the two input signals.

As shown in FIG. 2, the compensation system 228 further include one or more filters, such as filters 232-1, 232-2 that are coupled to input nodes (“SWA” and “SWB”) of the inductors 226-1, 226-2, respectively. As used herein, the term “filter” refers to an electronic circuit that allows certain frequencies or types of signals to pass through while attenuating or blocking others. The filter may be a low-pass filter (passing low frequencies and attenuates high frequencies), high-pass filter (passing high frequencies and attenuates low frequencies), or band-pass filter (BPF, passing a certain range of frequencies and attenuates frequencies outside this range), among others. Although embodiments are not so limited, the filters 232-1, 232-2 can each be a low-pass filter.

The comparator 228-2 can receive outputs from the filters 232-1, 232-2 as well as an output voltage (“VOUT” shown in FIG. 2) of the inductor 226-1 or the inductor 226-2 (or any combination thereof) as respective inverting inputs. Further, the comparator 228-2 can receive an output voltage from the error amplifier 228-1 as well as a reference voltage (“VREF” shown in FIG. 2) as respective non-inverting inputs. Therefore, the comparator 228-2 compares an aggregated combination of the non-inverting inputs (e.g., a combination of outputs from the error amplifier 228-1 and “VREF”) to an aggregated combination of the inverting inputs (e.g., a combination of “VOUT” and outputs of filters 232-1, 232-2) and generate an output corresponding to the difference between the two. The output from the comparator 228-2 is sent to the phase manager 246 where the output is distributed to the two phases. The outputs of the phase manager that goes to each phase can function as a signal indicative of (e.g., alternatively) activating the high-side switch 224-1-1, 224-2-1 of the phase circuits 231-1, 231-2.

The loop system 228 can operate to adjust the duty cycle of the converter's switches, thereby controlling “VOUT” to bring it closer to the target value defined by “VREF”. For example, when there is a change in “VOUT” (due to load transients, input voltage changes, or switching mode transitions), the error amplifier can detect the deviation from “VREF” and generates a corresponding adjustment signal. Accordingly, the settling time of the output voltage “VOUT” (e.g., how quickly it reaches its steady-state value after transitions, changes, etc.) can be influenced by how fast the error amplifier can respond to changes in the feedback loop.

The voltage regulator 213 further comprises a phase manager 246. The phase manager 246 can be a timing control circuit that generates signals to control the two phases based on the output from the comparator 228-2. The signals provided by the phase manager 246 to the two phase circuits 231-1, 231-2 can respectively indicate the driver logics 242-1 and 242-2 when to activate or deactivate the high-side switches 224-1-1, 224-2-1. This ensures that the switches 224 in each phase operate with precise timing while maintaining interleaving.

The phase manager 246 can operate in conjunction with a timer 248 in determining when to provide the signals to the two phase circuits 231-1, 231-2 (e.g., to indicate when to activate or deactivate the high-side switches 224-1-1, 224-2-1). Although embodiments are not so limited, the timer 248 can be an analog timer, which operates by generating timing signals using continuous electrical signals rather than digital clocks.

In some embodiments, a particular duration (alternatively referred to as “interleaving duration”), controlled by the timer 248, can be programmable through digital circuits that configure the timer's control parameters. For example, the interleaving duration can be set to 100 ns, 150 ns, or 200 ns. Further details of how the phase manager 246 operates in conjunction with the timer 248 are described in connection with FIGS. 3 and 4.

FIG. 3 is a flow diagram 350 corresponding to a method for operating a voltage regulator (e.g., the voltage regulator 113, 213 shown in FIGS. 1 and 2, respectively) with asymmetric phase interleaving in accordance with some embodiments of the present disclosure. More particularly, the voltage regulator 113, 213 can be selectively operated according to the flow diagram 350 during a CCM.

As used herein, the term “Continuous Conduction Mode (CCM)” refers to an operational mode of a power converter, such as a DC-DC converter, wherein an inductor current continuously flows throughout a switching period without returning to zero. In CCM, energy can be transferred to the output during both the on-time and off-time of a switching cycle, resulting in a continuous inductor current waveform.

As used herein, the term “Discontinuous Conduction Mode (DCM)” refers to an operational mode of a power converter, such as a DC-DC converter, wherein an inductor current ceases and returns to zero before the completion of a switching period. In DCM, energy can be transferred to the output during only a portion of the switching cycle, and the inductor remains de-energized for the remaining portion.

At 352 , the first phase circuit (e.g., the phase circuit 231-1 shown in FIG. 2) is in (e.g., put into) a wait state, which can be analogous to a NON state in a CCM. At 354, it is determined (e.g., by the phase manager 246 shown in FIG. 2) whether an output of the comparator (e.g., the comparator 228-2) corresponds to a particular logic state (e.g., “1”). If it is determined that the output does not correspond to the particular logic state, the flow diagram can proceed back to 352.

If it is determined that the output corresponds to the particular logic state, the flow diagram can proceed to 356, at which the phase manager 246 issues a “PON” signal to a driver logic (e.g., the driver logic 242-1 shown in FIG. 2) of the first phase circuit. As used herein, a signal “PON” is an activation signal that causes the driver 242-1, 242-2 to activate the high-side switch 224-1-1, 224-2-1 and a signal “NON” is another activation signal that causes the driver 242-1, 242-2 to activate the low-side switch 224-1-2, 224-2-2. Accordingly, a PON signal issued from the phase manager 246 to the driver logic 242-1 causes (e.g., signals) the driver logic 242-1 to activate the high-side switch (e.g., the high-side switch 242-1-1).

As used herein, a state, period, phase, cycle, etc. (e.g., in which the switch 224-1-1, 224-2-1 is in an activated state in response to the “PON” signal) is referred to as a PON cycle, a PON state, PON period, PON phase, PON cycle of the switch 224-1-1, 224-2-1, etc. Further, as used herein, a state, phase, cycle, etc., in which the switch 224-1-2, 224-2-2 is in an activated state in response to the “NON” signal is referred to as a NON cycle, a NON state, NON period, NON phase, NON cycle of the switch 224-1-2, 224-2-2, etc., respectively.

Once the PON signal is issued to the driver logic 242-1, at 357, the regulator 213 waits for the completion of a PON period (that has initiated from 356) of the first phase circuit. Alternatively speaking, at 357, it is determined whether the PON period is completed or not. Once it is determined that the PON period of the first phase circuit is completed, at 358, the timer (e.g., the timer 248 shown in FIG. 2) can begin measuring a particular duration (e.g., “T_{IL}” shown in FIG. 4) therefrom (e.g., from an initial time value). Alternatively speaking, the timer can measure the particular duration from the end of the PON cycle (e.g., PON period) of the high-side switch (e.g., the high-side switch 224-1-1 or 224-2-1). The flow diagram 350 then proceeds to 360, at which the second phase circuit (e.g., the phase circuit 231-2 shown in FIG. 2) is in (e.g., put into) a wait state. Alternatively, in some embodiments (particularly where the regulator 213 has a COT for those PON cycles of the switches 224-1-1, 224-2-1 that are predetermined or known), the timer 248 can begin (e.g., at the step 356) measuring a particular duration (e.g., “D T_{SW}+T_{IL}” shown in FIG. 4) from the start (e.g., beginning) of the duty cycle (e.g., the PON period of the first phase circuit).

At 362, it is determined (e.g., by the phase manager 246 shown in FIG. 2) whether an output of the comparator (e.g., the comparator 228-2) corresponds to a particular logic state (e.g., “1”, which indicates the need for one of the phases to turn on their high side switch 224-1-1 or 224-2-1) or the timer 248 is indicated to have expired (e.g., indicated to have elapsed for a particular duration or period, such as “T_{IL}” shown in FIG. 3 or FIG. 4). If it is determined that the output does not correspond to the particular logic state and the timer 248 is indicated to have expired, the flow diagram can proceed back to 360.

If it is determined that the output corresponds to the particular logic state or the timer 248 is indicated to have expired or the comparator 282-2 provides an output corresponding to logic “1”, the flow diagram can proceed back to 364, at which the timer 248 can be reset such that the timer 248 can clock a new timing cycle (e.g., for the particular duration) from the initial value. Subsequent to resetting the timer 248, the flow diagram 350 can further proceed to 366, at which the phase manager 246 issues a “PON” signal to a driver logic (e.g., the driver logic 242-2 shown in FIG. 2) of the second phase circuit. Accordingly, a PON signal issued from the phase manager 246 to the driver logic 242-2 causes (e.g., signals) the driver logic 242-2 to activate the high-side switch (e.g., the high-side switch 242-2-1). Subsequent to issuing the PON signal to the driver logic 242-2, the flow diagram 350 can proceed to 367, at which it is determined whether a PON period of the second phase circuit (that has initiated from 366) is completed or not. If it is determined that the PON period of the second phase circuit is completed, the flow diagram can proceed back to 352.

FIG. 4 illustrates graphs showing currents of inductors of a voltage regulator (e.g., regulator 113, 213 shown in FIGS. 1 and 2, respectively) exhibiting asymmetric interleaving in accordance with some embodiments of the present disclosure. More particularly, the graphs illustrated in FIG. 4 show the states of various signals when the voltage regulator 113, 213 is selectively operated during a CCM.

Graph 471 shows states of a current flowing over an inductor (e.g., the inductor 226-1 shown in FIG. 2) of the first phase circuit (e.g., the phase circuit 231-1 shown in FIG. 2), while graph 473 shows states of a current flowing over an inductor (e.g., the inductor 226-2 shown in FIG. 2) of the second phase circuit (e.g., the phase circuit 231-2 shown in FIG. 2). Further, graph 475 shows the states of a current corresponding to the sum of the currents flowing through inductors 226-1 and 226-2, which further corresponds to the output current of the voltage regulator (corresponding to “VOUT” shown in FIG. 2). This signal also can be indicative of the compensation ramp at the output of the filters 232-1 and 232-2.

As shown in FIG. 4, each phase circuit has a switching period (shown as “T_{SW}”), which corresponds to the total duration of one complete cycle of the switching operation, during which the high-side and low-side switches of the respective phase circuit are activated and deactivated sequentially. Further, “D” shown in FIG. 4 represents a duty cycle for the respective phase circuit that corresponds to the ratio of the ON-time of the high-side switch to the total switching period (“T_{SW}”).

For example, assuming that the graph 471 corresponds to the phase circuit 231-1, through which the current IL_{PH1} flows, the PON cycle during which the high-side switch 224-1-1 is activated (alternatively referred to as a PON period of the phase circuit) corresponds to the duration from time 470 (e.g., the initial time of the graph 471) to time 472. Continuing with this example, the duration from time 472 to time 478 on graph 471 corresponds to the period during which the low-side switch 224-1-2 is activated (e.g., while the high-side switch 224-1-1 is deactivated).

Similarly, assuming that the graph 472 corresponds to the phase circuit 231-2, through which the current IL_{PH2} flows, the PON cycle during which the high-side switch 224-2-1 is activated (alternatively referred to as a PON period of the phase circuit) corresponds to the duration from time 474 (e.g., the initial time of the graph 473) to time 476. Continuing with this example, the duration from time 476 to time 480 on graph 473 corresponds to the period during which the low-side switch 224-2-2 is activated (e.g., while the high-side switch 224-2-1 is deactivated).

As further shown in graph 475, the two phase circuits 231-1, 231-2 are asymmetrically interleaved. In some approaches, the control loop would have generated a PON signal (e.g., representing the activation of the high-side switch for a given phase circuit, such as switch 224-1-1, 224-2-1 shown in FIG. 2) for one phase (e.g., the second phase 231-2) at

$$\frac{{T}_{s w}}{2} .$$

In contrast, embodiments of the present disclosure modify the control loop to generate the PON signal for the second phase at DT_{SW}+T_{IL}. For example, the control loop (e.g., the compensation loop 228 shown in FIG. 2) issue the PON signal to one phase after waiting a duration of “T_{IL}” (corresponding to the duration from time 472 to time 474) in addition to the PON period of another phase.

More particularly, a PON signal is issued (e.g., from the phase manager 246 shown in FIG. 2) to the phase circuit 231-2 subsequent to a sum of a PON period and a T_{IL} (e.g., corresponding to the period from the time 470 to the time 474). Therefore, the inductor current (and compensation ramp) shown by graph 473 increases from the time 474 as a result of the issuance of the PON signal. Unlike some approaches, where the two phases are interleaved by 180°, this programmable interleaving delay “T_{IL}” allows the sum of two currents (shown by graph 475) to increase again once the interleaving delay is indicated to have elapsed, resulting in a higher peak of inductor current(and compensation ramp) as compared to methods which employ “symmetric interleaving”.

In a number of embodiments, the asymmetric phase interleaving technic described herein can enhance the system's immunity to jitter and noise across a wide range of duty cycles by improving compensation ramp height. In some approaches, compensation ramp height may increase, indicating poorer load application transient response. In contrast, in a number of embodiments of the present disclosure, although the compensation ramp height is increased, transient performance is improved because the loop is transparent to decisions made by the comparator (between times 427 and 474) . The increase in compensation ramp height reduces the systems susceptibility to noise. Although jitter may occur within a small window corresponding to “T_{IL}” (e.g., where the compensation ramp height is relatively low, making the control logic more transparent to comparator decisions), the resulting jitter can remain constrained since “T_{IL}” is relatively short in duration.

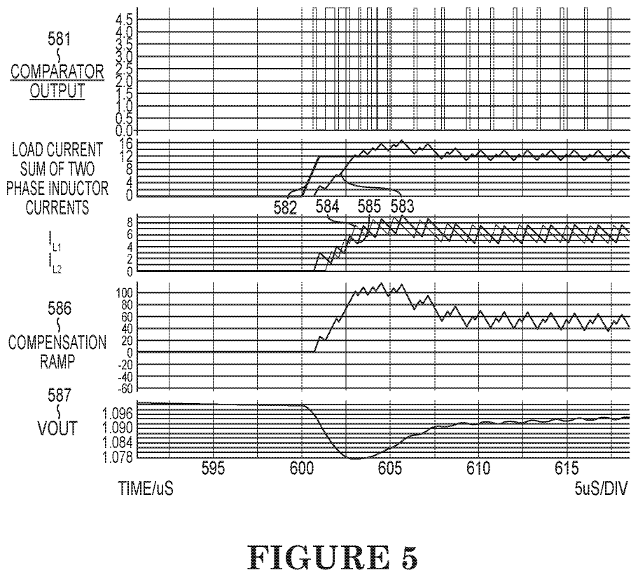

FIG. 5 illustrates graphs showing states of various signals during operation of a regulator (e.g., the regulator 113, 213 respectively shown in FIGS. 1 and 2) during a load application transient in accordance with some embodiments of the present disclosure. More particularly, the graphs illustrated in FIG. 5 show the states of various signals when the voltage regulator 113, 213 is selectively operated during a CCM.

Graph 581 shows the output of the comparator (e.g., the comparator 228-2 shown in FIG. 2). Graph 582 shows a sum of the inductor currents (e.g., the currents flowing through the inductor 226-1, 226-2 shown in FIG. 2) and the load current (e.g., the current flowing from the output of the converter into the load).

Graphs 584 and 585 respectively show inductor currents (e.g., the currents respectively flowing through the inductor 226-1, 226-2 shown in FIG. 2). Graph 586 shows a compensation ramp (e.g., output of filters 232-1 and 232-2 shown in FIG. 2). Graph 587 shows the nature of “VOUT” signal, which corresponds to an output voltage of the regulator 213.

As illustrated in FIG. 5, embodiments of the present disclosure address challenges typically associated with poor transient responses caused by increased ramp heights or the addition of external ramps. In some approaches, enhancing ramp heights or adding external ramps can improve noise immunity but often leads to degraded load transient performance, characterized by larger undershoots or overshoots during load transitions.

In contrast, embodiments of the present disclosure leverage an asymmetric interleaving strategy managed by a phase manager (e.g., the phase manager 246 shown in FIG. 2) to improve (e.g., heighten) ramp heights without compromising transient performance. FIG. 5 shows that, despite the improved ramp heights shown by graph 586, the load transient response remains intact as shown in graph 587. More particularly, the undershoot observed during load transitions in the asymmetric interleaving approach described herein is approximately 23 millivolts (mV), which can be comparable to that of the symmetric interleaving approaches with poorer ramp heights. This ensures that the noise immunity benefits achieved by improved ramp heights do not come at the cost of degraded load transient performance.

In a number of embodiments, the asymmetric phase interleaving technique employed in the voltage regulator 113, 213 (e.g., DC-DC step-down converter) still exhibits comparable frequency characteristics to conventional methods at lower frequencies. In some embodiments, at higher frequencies beyond the unity gain bandwidth (UGB) of the control loop (e.g., either one of the phase circuits 231-1, 231-2 shown in FIG. 2), differences may emerge between the conventional architecture and the proposed asymmetric phase interleaving approach described herein may introduce a marginal phase margin degradation that does not significantly impact the stability or performance of the system. Accordingly, the asymmetric phase interleaving approach ensures that the overall loop stability remains unaffected while optimizing phase timing to achieve improved system performance.

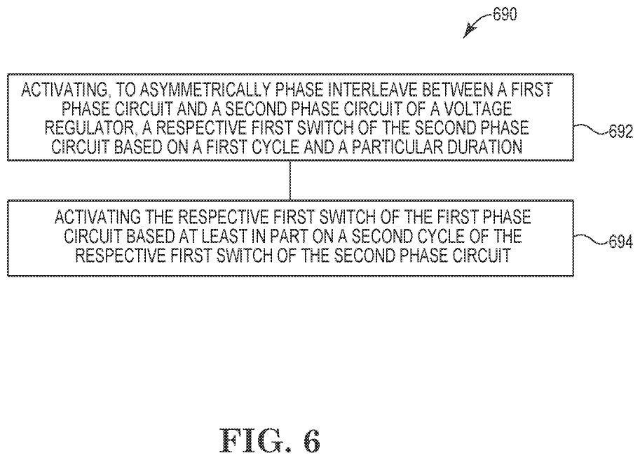

FIG. 6 is a flow diagram corresponding to a method for operating a voltage regulator with asymmetric phase interleaving in accordance with some embodiments of the present disclosure. The method 690 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 690 is performed by the voltage regulator 113, 213 of FIGS. 1 and 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 692, asymmetrical phase interleaving can be performed by activating a first phase circuit (e.g., the phase circuit 231-1 shown in FIG. 2) and a second phase circuit (e.g., the phase circuit 231-1 shown in FIG. 2) of a voltage regulator (e.g., the voltage regulator 113, 213 shown in FIGS. 1 and 2, respectively), a respective first switch (e.g., the switch 224-2-1 shown in FIG. 2) of the second phase circuit. This can be performed based on a first cycle (e.g., “D T_{SW}” shown in FIG. 4) of a respective first switch (e.g., the switch 224-1-1 shown in FIG. 2) of the first phase circuit and a particular duration measured respective to the first cycle. More particularly, activating the respective first switch 224-2-1 of the second phase circuit 231-2 can include measuring the particular duration respective to the end of the first cycle (e.g., responsive to a signal generated subsequent to an end of the first cycle and indicative of activating the respective first switch 224-2-1 of the second phase circuit 231-2) and activating the respective first switch 224-2-1 of the second phase circuit 231-2 after the particular duration is determined to have elapsed from the end of the first cycle.

In some embodiments, the particular duration (e.g., “T_{IL}” shown in FIG. 4) can be measured from the beginning of the first cycle. Alternatively, the particular duration (e.g., “DT_{SW}+T_{IL}” shown in FIG. 4) can be measured from an end of the first cycle.

At 694, the respective first switch 224-1-1 of the first phase circuit 231-1 can be activated based at least in part on a second cycle (e.g., from the time 474 to the time 476 shown in FIG. 4) of the respective first switch 224-2-1 of the second phase circuit 231-2. This can include activating the respective first switch 224-1-1 of the first phase circuit 231-1 based at least in part on comparison among an output voltage (“VOUT” shown in FIG. 2) of the voltage regulator, voltages on input nodes (“SWA”, “SWB” shown in FIG. 2) of respective inductors of the first and second phases, and one or more reference voltages (“VREF” input to the error amplifier 228-1 or “VREF” input to the comparator 228-2), or any combination thereof.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
activating, to asymmetrically phase interleave between a first phase circuit and a second phase circuit of a voltage regulator, a respective first switch of the second phase circuit based at least in part on:
a first cycle during which a respective first switch of the first phase circuit is activated; and
a particular duration measured respective to the first cycle; and
activating the respective first switch of the first phase circuit based at least in part on a second cycle during which the respective first switch of the second phase circuit.

2. The method of claim 1, wherein activating the respective first switch of the first phase circuit based in part on the second cycle comprises:
activating the respective first switch of the first phase circuit based at least in part on comparison among an output voltage of the voltage regulator, voltages on input nodes of respective inductors of the first and second phases, and one or more reference voltages, or any combination thereof.

3. The method of claim 1, wherein activating the respective first switch of the second phase circuit based in part on the first cycle comprises:
responsive to a signal generated subsequent to an end of the first cycle and indicative of activating the respective first switch of the second phase circuit:
measuring the particular duration respective to the end of the first cycle; and
activating the respective first switch of the second phase circuit after the particular duration is determined to have elapsed from the end of the first cycle.

4. The method of claim 3, wherein measuring the particular duration respective to the end of the first cycle further comprises measuring the particular duration from a beginning of the first cycle.

5. The method of claim 3, wherein measuring the particular duration respective to the end of the first cycle further comprises measuring the particular duration from an end of the first cycle.

6. A voltage regulator, comprising:
a first phase circuit comprising a first inductor coupled to a respective first switch and a respective second switch of the first phase circuit that are respectively coupled to a power source and ground;
a second phase circuit comprising a second inductor coupled to a respective first switch and a respective second switch of the second phase circuit that are respectively coupled to a power source and ground; and
a phase manager configured to:
cause the respective first switch of the first phase circuit to be activated in response to a signal indicative of activation of the respective first switch of the first phase circuit; and
cause, to asymmetrically phase interleave between the first and second phase circuits, the respective first switch of the second phase circuit to be activated in response to a particular period being determined to have elapsed, wherein the particular period is measured respective to a first cycle during which the respective first switch of the first phase circuit.

7. The voltage regulator of claim 6, wherein the phase manager further comprises a timer configured to indicate whether the particular period has elapsed.

8. The voltage regulator of claim 7, wherein the timer is configured to measure the particular period from a beginning of the first cycle.

9. The voltage regulator of claim 7, wherein the timer is configured to measure the particular period from an end of the first cycle.

10. The voltage regulator of claim 7, wherein the signal is generated based on one or more comparisons among respective inductor currents of the first phase circuit and the second phase circuit, an output voltage of the voltage regulator, a reference voltage, or any combination thereof.

11. The voltage regulator of claim 6, wherein the voltage regulator is a constant on time (COT) voltage regulator, in which a time period corresponding to the first cycle is known or predetermined.

12. The voltage regulator of claim 6, wherein the voltage regulator is a dual-phase voltage regulator.

13. A voltage regulator, comprising:
a first phase circuit comprising a first inductor coupled to a respective first switch and a respective second switch of the first phase circuit that are respectively coupled to a power source and ground;
a second phase circuit comprising a second inductor coupled to a respective first switch and a respective second switch of the second phase circuit that are respectively coupled to a power source and ground; and
a compensation circuit configured to:
cause the respective first switch of the second phase circuit to be activated based at least in part on:
a first cycle during which the respective first switch of the first phase circuit; and
a particular duration measured respective to the first duty cycle;
cause the respective first switch of the first phase circuit to be activated based at least in part on a second duty cycle during which the respective first switch of the second phase circuit.

14. The voltage regulator of claim 13, wherein the compensation circuit further comprises:
an error amplifier configured to compare an output voltage of the voltage regulator to a first reference voltage; and
one or more filters respectively coupled to input nodes of the first inductor and the second inductor.

15. The voltage regulator of claim 14, wherein the compensation circuit further comprises a comparator configured to:
perform one or more comparisons among the output voltage, an output of the error amplifier, filtered signals respectively received from the one or more filters, and a second reference voltage, or any combination thereof.

16. The voltage regulator of claim 15, wherein the comparator is configured to:
periodically generate a signal indicative of activating the respective first switch of the first phase circuit or the respective first switch of the second phase circuit based at least in part on the one or more comparisons performed among the output voltage, the output of the error amplifier, the filtered signals respectively received from the one or more filters, and the second reference voltage, or any combination thereof.

17. The voltage regulator of claim 16, wherein the compensation circuit is configured to:
cause the respective first switch of the first phase circuit to be activated in response to the signal generated from the comparator; and
cause the respective first switch of the second phase circuit to be activated in response the particular duration measured respective to the first cycle being determined to have elapsed or the signal generated from the comparator.

18. The voltage regulator of claim 13, further comprising a timer to measure the particular duration respective to the first cycle.

19. The voltage regulator of claim 18, wherein the voltage regulator is configured to cause the timer to measure the particular duration from an initial value from a beginning of the first cycle.

20. The voltage regulator of claim 18, wherein the voltage regulator is configured to cause the timer to measure the particular duration from an initial value from an end of the first cycle.
